(19) United States
(12) Patent Application Publication
(10) Pub. No.: US 2024/0322843 A1
(43) Pub. Date: Sep. 26, 2024

(54) DETERMINING BERLEKAMP DISCREPANCY VALUES

(71) Applicant: Microchip Technology Incorporated, Chandler, AZ (US)

(72) Inventors: Diego Felipe Gomes Coelho, Calgary (CA); Peter Graumann, Calgary (CA)

(21) Appl. No.: 18/611,441

(22) Filed: Mar. 20, 2024

Related U.S. Application Data
(60) Provisional application No. 63/491,257, filed on Mar. 20, 2023.

(51) Int. Cl. H03M 13/15; G06F 17/16

(52) U.S. Cl. CPC H03M 13/153; G06F 17/16; H03M 13/1515

(57) ABSTRACT

A method may include generating a first computational circuit of a current iteration of a Berlekamp algorithm, the first computational circuit to determine a Berlekamp discrepancy value at least partially based on a current Error-Locator Polynomial (ELP) and observed syndromes; and generating a second computational circuit of the current iteration of the Berlekamp algorithm, the second computational circuit to determine an intermediate value, the intermediate value useable by one or more first computational circuits of one or more subsequent iterations of the Berlekamp algorithm to determine Berlekamp discrepancy values.

### CROSS-REFERENCE TO RELATED APPLICATION

This application claims the benefit under 35 U.S.C. § 119(e) of U.S. Provisional Patent Application Ser. No. 63/491,257, filed Mar. 20, 2023, the disclosure of which is hereby incorporated herein in its entirety by this reference.

### FIELD

One or more examples relate, generally, to determining Berlekamp discrepancy value utilized to determine Error-Locator Polynomial of the type used, for example in Reed Solomon (RS) decoders and Bose-Chaudhuri-Hocquenghem (BCH) decoders.

### BACKGROUND

An error locator polynomial (ELP) is a polynomial expression where the roots of the expression represent the error pattern in a block of data. ELPs are utilized in a variety of operational contexts, including Reed Solomon (RS) decoders and Bose-Chaudhuri-Hocquenghem (BCH) decoders.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram depicting an apparatus to determine an Error-Locator-Polynomial (ELP), in accordance with one or more examples.

FIG. 2 is a block diagram depicting a Berlekamp discrepancy determination circuit in accordance with one or more examples.

FIG. 3A through FIG. 3G are schematic diagrams depicting instances of computational circuits that may be generated by a discrepancy determination circuit 200 of FIG. 2 to determine Berlekamp discrepancy values, intermediate values, or both, during various iterations of a Berlekamp algorithm, in accordance with one or more examples.

FIG. 4 is a block diagram depicting an apparatus to determine an Error-Locator-Polynomial (ELP) at least partially based on a status signal, where the status signal indicates the status of an ELP determination (Berlekamp algorithm), in accordance with one or more examples.

FIG. 5 illustrates an example process for a Berlekamp discrepancy determination, in accordance with one or more example.

FIG. 6 illustrates an example process for generating the first computational circuit of the current iteration of the Berlekamp algorithm, in accordance with one or more examples.

FIG. 7 illustrates an example process for generating the first computational circuit and the second computational circuit of the current iteration of the Berlekamp algorithm, in accordance with one or more examples.

FIG. 8 illustrates an example process for generating the first computational circuit and the second computational circuit of the current iteration of the Berlekamp algorithm, in accordance with one or more examples.

FIG. 9 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

A typical approach to solve for the error locator polynomial (ELP) is to complete all 2*t iterations of a Berlekamp-Massey (“Berlekamp”) algorithm, where t is the highest number of errors correctable by a respective instance of the Berlekamp algorithm. The Berlekamp algorithm continues evolving an ELP even after converging on an ELP.

This allows the ELP determination to have consistent latency (e.g., always have the same latency, without limitation), which reduces the burden of integration into any overall circuit flow within a device. Typical RS decoders try and maintain consistent latency regardless of the number of errors in a Forward Error Corrected (FEC) data block (“FEC block”). In real system operation, those FEC blocks that have a low number of errors (0 or 1 symbols that are erred) are the most common while those that have t or t−1 errors are rare. Nevertheless, a standard Reed Solomon decoder typically must maintain full system throughput even for the FEC blocks that have t or t−1 errors.

The latency of a typical RS decoder is related to the highest number of errors that could be corrected by the decoder for a given application. The ELP calculation generally utilizes 2*t iterations to complete, where t is the highest error correction capacity of the decoder. For latency critical systems, it is desirable to reduce the RS decoder latency.

During respective iterations of an ELP determination, the Berlekamp algorithm determines a discrepancy value (also referred to herein as a “Berlekamp discrepancy value”) that represents a difference between the error pattern detectable by a current version of the ELP (respective current versions of an ELP over various iterations are referred to herein as a “current ELP”) and an error pattern indicated by a syndrome.

The Berlekamp discrepancy value is typically determined based on a difference between a syndrome (determined by a syndrome calculator) and a syndrome calculated from a current estimate of the ELP (“current ELP”). To determine the syndrome from the current ELP, the current ELP is evaluated at certain points related to the syndrome derived from a codeword. If the discrepancy value at an iteration is zero then the current ELP is sufficient to locate error conditions completed to that point, and no update to the candidate ELP is required. If the discrepancy value at an iteration is non-zero then the current ELP is not sufficient to locate error conditions completed to that point and the ELP is updated based on the discrepancy value. If all future DC values are also zero then the current ELP is the final ELP.

If the discrepancy is non-zero, the Berlekamp algorithm updates the ELP using a combination of a previous version of the current ELP and a further polynomial, referred to herein as a “discrepancy polynomial.” The discrepancy polynomial is scaled (multiplied by a factor related to the discrepancy) and then added to the current ELP. In finite field arithmetic, this is analogous to multiplying polynomials where coefficients are elements of the field.

In typical implementations of the Berlekamp algorithm, discrepancy values and changes to the ELP are determined using direct equations.

The number of operators (e.g., multipliers, adders, without limitation) utilized to calculate the discrepancy values and/or changes to the ELP typically increases with each iteration of the Berlekamp-Massey algorithm. A typical error locator polynomial (ELP) determination circuit includes a number of operators (e.g., multipliers, adders, without limitation) equal to the highest number of operators that could be required to calculate a Berlekamp discrepancy value—i.e., if all 2*t iterations of the Berlekamp algorithm are performed.

Accordingly, typical hardware implementations of the Berlekamp algorithm require multiple multipliers to calculate the discrepancy values because the discrepancy calculation typically involves multiple operations over finite fields (like GF(2\hat{ }m) for Reed-Solomon codes), which are typically implemented as multipliers in hardware. Each act may require fresh calculations based on the current ELP and observed syndromes, leading to a significant number of multipliers if every operation is done independently (e.g., without reusing hardware resources, without limitation).

The inventors of this disclosure appreciate that the observed syndromes used in the calculation of discrepancy values remain constant throughout the Berlekamp algorithm. This consistency may be exploited by storing (or “registering”) intermediate values instead of recalculating them at every act, the enhanced Berlekamp algorithm reduces the need for continuous use of multipliers.

Further, the inventors of this disclosure appreciate that by formulating the discrepancy calculations based on Winograd's algorithm for vector inner product, there are more opportunities to store intermediate values (as compared to direct equations for calculating discrepancy values used in the typical Berlekamp algorithm). Using Winograd's algorithm reduces the number of multiplications needed to perform matrix operations. By applying similar principles to the calculation of discrepancy values, the number of multiplications required may be reduced, accordingly, the number of multipliers required may be reduced.

Further still, the inventors of this disclosure appreciate that in some or even most iterations of the Berlekamp algorithm, fewer than a totality of available operators are utilized, thus, some operators may be inactive (or at least not used by the ELP determination circuit) during a given iteration of the Berlekamp calculation.

One or more examples relate, generally, to using (and reusing) multipliers across different acts of a Berlekamp algorithm formulated based on Winograd's algorithm. In hardware, multipliers are significant resources. Using multipliers that are inactive (i.e., not being used at certain times in the algorithm) and storing the results reduces the hardware requirements to implement the enhanced Berlekamp algorithm as compared to typical implementations of the Berlekamp algorithm.

Examples discussed herein, generally, improve the efficiency of Berlekamp discrepancy determination by reducing the hardware resources used, for example, number of multipliers.

Efficient use of operators during various iterations of the Berlekamp algorithm may reduce one or more of: the number of operations performed during various iterations of the Berlekamp-Massey algorithm, the latency of Reed Solomon (RS) decoders and Bose-Chaudhuri-Hocquenghem (BCH) decoders that utilize the same, or the number of operators included with an ELP determination circuit and RS and BCH decoders more generally.

As used herein, “codeword” means a sequence of symbols.

As used herein, “error” means a difference between a current form of a codeword and the original or intended form of the codeword. Non-limiting examples of errors include symbol errors, burst errors, or erasure errors, without limitation. Such differences may be caused, as non-limiting examples, during transmission (e.g., via an electronic communication system, without limitation) or storage (e.g., via a data storage device, without limitation) of a codeword.

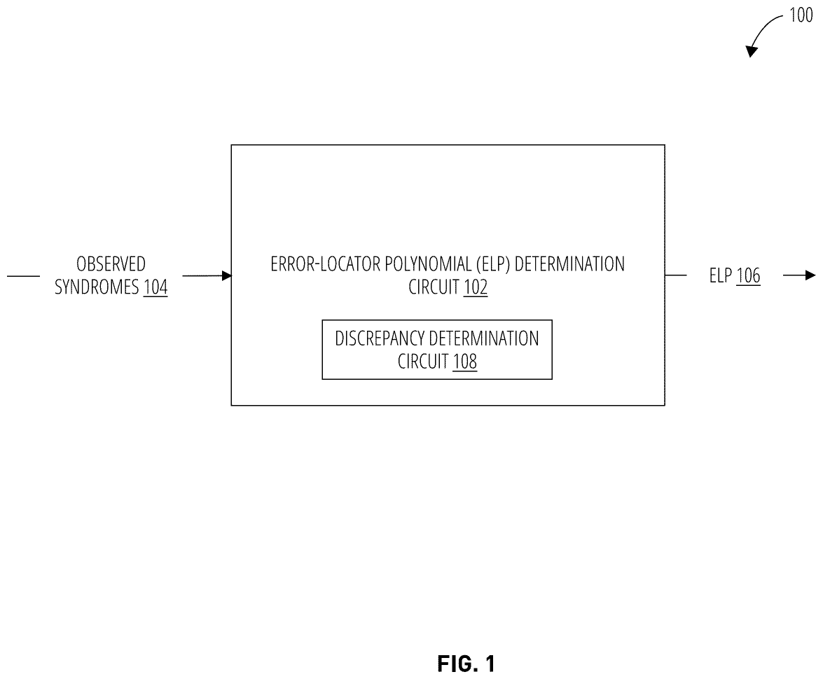

FIG. 1 is a block diagram depicting an apparatus 100 to determine an Error-Locator-Polynomial (ELP), in accordance with one or more examples.

Error-Locator Polynomial (ELP) determination circuit 102 generates an ELP 106 at least partially based on observed syndromes 104. ELP determination circuit 102 determines ELP determination circuit 102 over one or more iterations at least partially based on observed syndromes 104. ELP determination circuit 102 determines ELP 106 having coefficients that indicate the locations of one or more errors (if any errors are present) in a codeword associated with observed syndromes 104.

Observed syndromes 104 indicate the presence of errors (and implicitly or explicitly the absence of errors) in a codeword and indicate the locations of the errors in the codeword. The locations of errors in a codeword may also be referred to herein as an “error pattern.” Respective syndromes correspond to respective, specific error patterns. For a given code (e.g., FEC encoding technique, without limitation) that can correct up to terrors, 2*t observed syndromes 104 are determined on a codeword.

Respective observed syndromes 104 are syndromes calculated directly from the codeword (received data) before any error correction is applied. Observed syndromes 104 may be received by ELP determination circuit 102 from a syndrome calculator (syndrome calculator not depicted). The coefficients of ELP 106 are set so the locations of errors in the codeword associated with observed syndromes 104 may be determined at least partially based on the coefficients, as discussed below. In one or more examples, observed syndromes 104 are vectors of syndromes (e.g., a vector of syndromes includes one or more syndromes, without limitation).

In one or more examples, ELP determination circuit 102 determines ELP 106 at least partially based on execution of the Berlekamp algorithm. During an ELP determination, the Berlekamp algorithm iteratively refines an ELP, including changing the coefficients of the ELP. By the end of the final, ith, iteration, the Berlekamp algorithm has evolved (e.g., changed, without limitation) the ELP such that the discrepancy value (V*ELP−Si)=0, where Si is the ith syndrome of a vector of v syndromes [Si−1, Si−2, . . . , Si−v] denoted by their subscripts, and the ELP (e.g., ELP 106, without limitation) is a vector of v coefficients [C1, C2, . . . , Cv] of the ELP.

During respective iterations, the Berlekamp algorithm determines discrepancy values via discrepancy determination circuit 108 (discussed below). The discrepancy values represent a difference between an error pattern indicated by a current version of the ELP and an error pattern indicated by a current syndrome of the observed syndromes 104. As a non-limiting example, a discrepancy value of zero indicates no difference, a discrepancy value that is non-zero indicates a difference. A zero-discrepancy value implies that all errors represented by a current syndrome are detectable by the current ELP. A non-zero discrepancy value implies that all errors represented by a current syndrome are not detectable by the current ELP.

The Berlekamp algorithm changes the coefficients of the ELP to account for the discrepancy values, i.e., to reduce the difference between the error patterns indicated by a current ELP and error patterns indicated by observed syndromes 104. The iterative process continues until the Berlekamp algorithm converges on an ELP that accurately detects the error patterns indicated by the observed syndromes 104. When the Berlekamp algorithm of ELP determination circuit 102 determines that a current ELP accurately detects the error patterns indicated by observed syndromes 104, then the Berlekamp algorithm does not change the coefficients of the ELP any further and outputs the current ELP as the ELP 106.

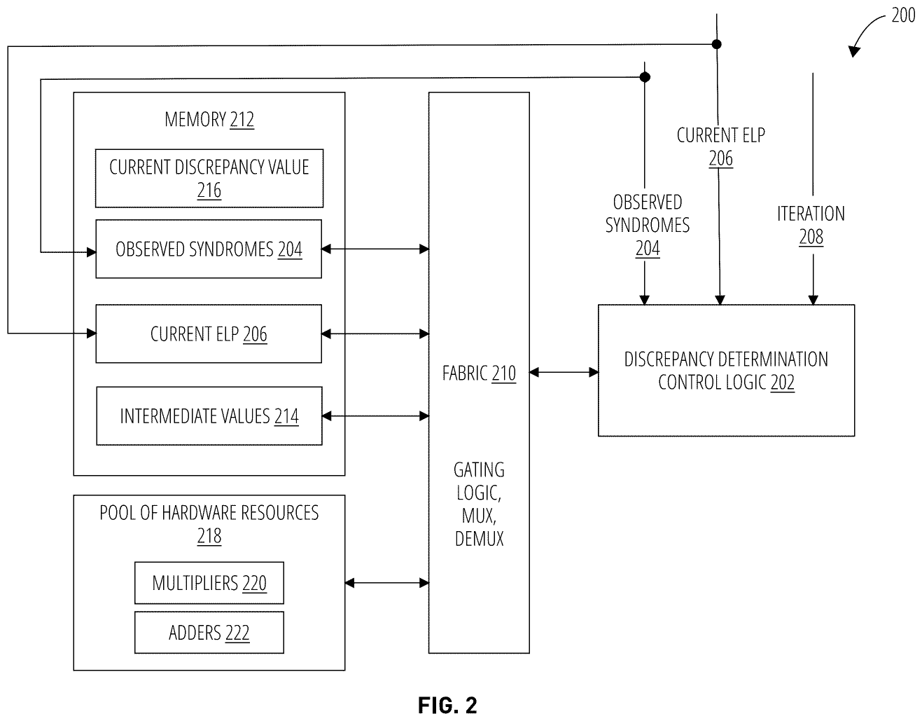

FIG. 2 is a block diagram depicting a discrepancy determination circuit 200 in accordance with one or more examples.

Discrepancy determination circuit 200 includes discrepancy determination control logic 202, fabric 210, memory 212 and pool of hardware resources 218.

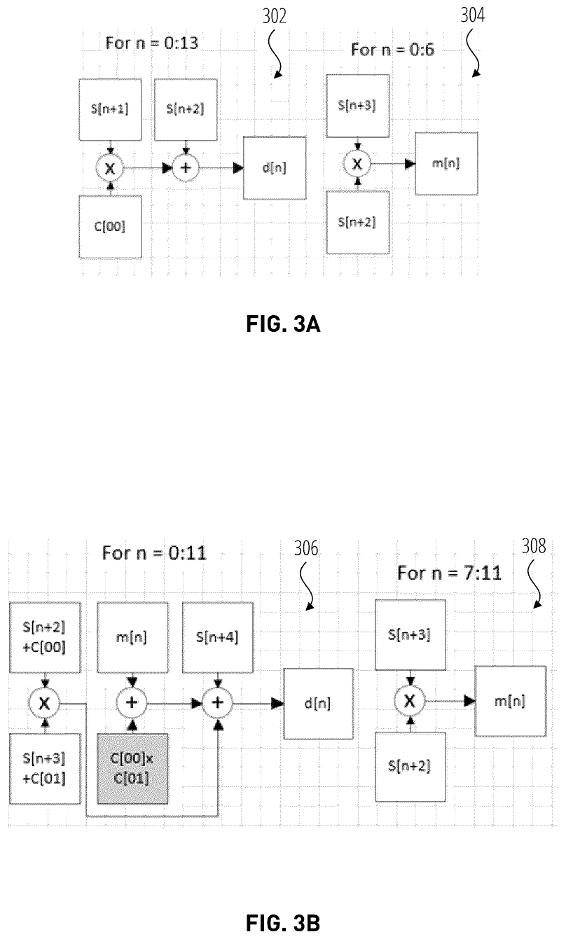

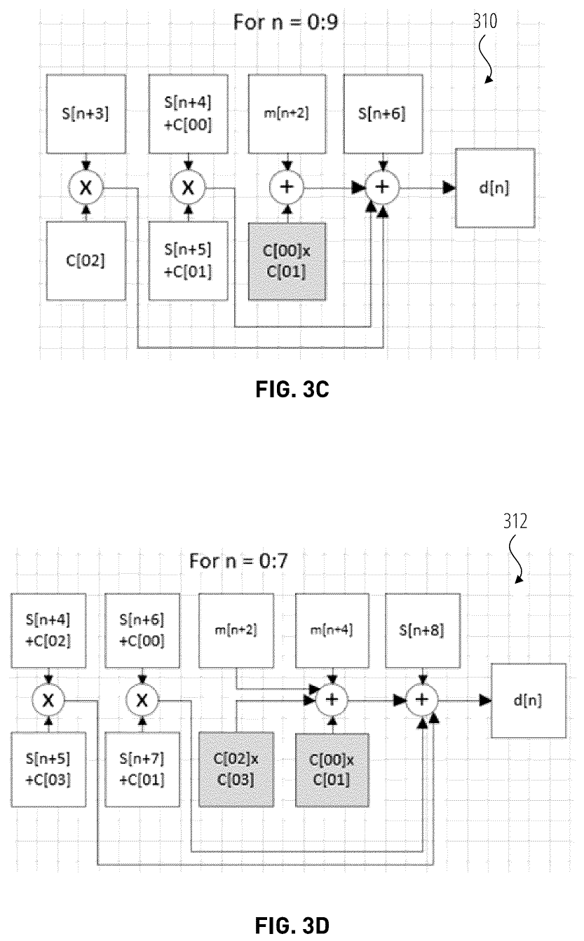

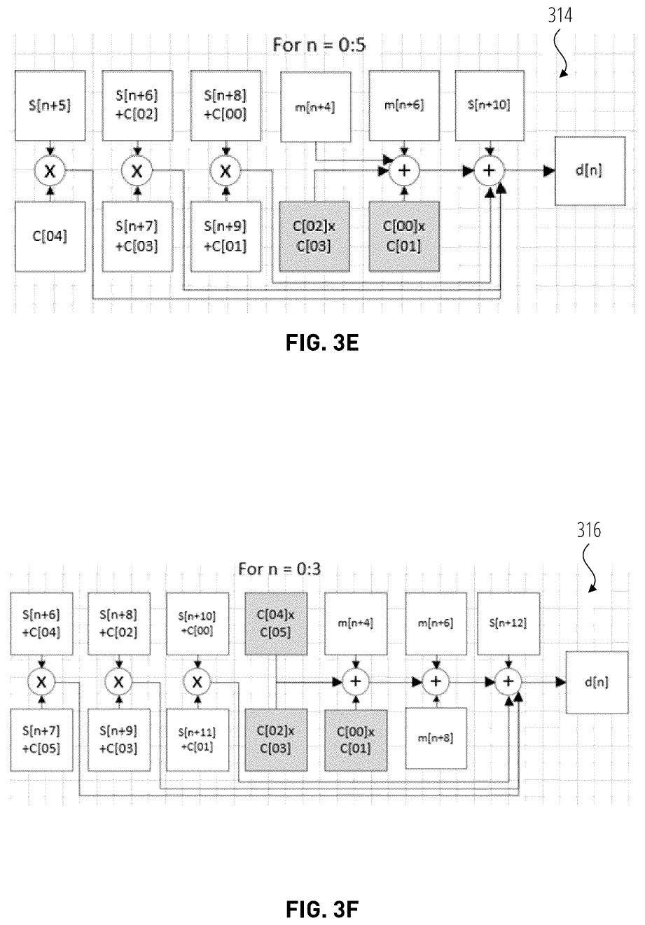

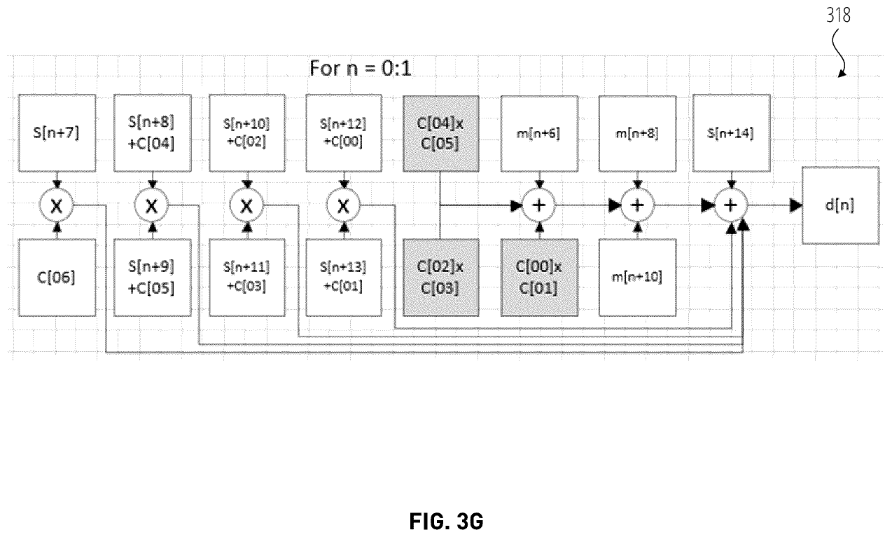

Discrepancy determination control logic 202 dynamically assigns resources (multipliers 220 and adders 222) from pool of hardware resources 218 to cause the generation of various computational circuits (including one or more of computational circuits depicted by FIG. 3A, FIG. 3B, FIG. 3C, FIG. 3D, FIG. 3E, FIG. 3F, and FIG. 3G, discussed below, without limitation). In one or more examples, discrepancy determination control logic 202 may be based on the needs of the current iteration and the availability of these resources. Discrepancy determination control logic 202 determines specific operations to be performed based on the respective iteration indicated by iteration 208 and assigns the multipliers 220 and adders 222 from the pool of hardware resources 218 via fabric 210 to generate respective computational circuits for determining discrepancy values, intermediate values, or both. Operations or computational circuits for respective iterations of the Berlekamp algorithm may be predetermined and stored at discrepancy determination control logic 202.

The pool of hardware resources 218 is a collective set of hardware resources, including, but not limited to, multipliers 220 and adders 222, that are available to be used (e.g., dynamically assigned by discrepancy determination control logic 202, without limitation) for various computations within a digital circuit. Multipliers 220 and adders 222 of pool of hardware resources 218 are not permanently dedicated to a single task or circuit, and so may be assigned to different functions or operations by discrepancy determination control logic 202. Since these resources are pooled, they may be shared among different computational circuits or tasks. For example, a multiplier of multipliers 220 might be used at one moment (e.g., corresponding to a current iteration of the Berlekamp algorithm, without limitation) for a discrepancy determination and at another moment (e.g., corresponding to a later iteration of the Berlekamp algorithm, without limitation) for determining intermediate values or, optionally, other unrelated computations.

Memory 212 stores observed syndromes 204, current ELP 206, intermediate values 214 and current discrepancy value 216. Memory 212 may include any suitable non-transitory storage mediums such as flip-flops, registers, or other suitable memory devices, without limitation. Observed syndromes 204 indicate the presence of errors (and implicitly or explicitly the absence of errors) in a codeword and indicate the locations of the errors in the codeword, and may be the same as observed syndromes 104. Current ELP 206 is a current estimate of the ELP determined by the ELP determination circuit 102 and being evaluated by discrepancy determination circuit 200 (and discrepancy determination control logic 202 more specifically) during the current iteration of the Berlekamp algorithm. Intermediate values 214 are the various intermediate values determined by discrepancy determination control logic 202 in a current iteration or previous iterations of the Berlekamp algorithm.

Fabric 210 may include one or more of multiplexers, demultiplexers, or combinational and sequential logic circuits, controlled by discrepancy determination control logic 202 to setup computational circuits to determine discrepancy values and intermediate values and store the results in memory 212 as current discrepancy value 216 or intermediate values 214, as the case may be.

### Calculation of Discrepancy Values and Intermediate Values

In one or more examples, discrepancy determination control logic 202 may use matrix math to evaluate the current ELP 206. For example, discrepancy determination control logic 202 may construct a first matrix including 2*t−2*v rows, where a respective row includes syndromes (taken from observed syndromes 204), and a second matrix of coefficients C₁ to Cᵥ of the current ELP 206. a third matrix of observed syndromes; and a fourth matrix of discrepancy values. The result of multiplying the first matrix with the second matrix is a matrix of values. Here, ‘v’ is an integer greater than or equal to 1, and also represents a current iteration being evaluated.

The result of multiplying the first matrix with the second matrix is compared to the values in the third matrix, and if the values are the same then the result will be zero values in the fourth matrix. If the values in the result matrix and third matrix are different then the result will be non-zero discrepancy values in the fourth matrix. In this specific example, the addition operation refers to verifying whether or not two quantities are the same.

In one or more examples, the computations controlled by discrepancy determination control logic 202 to perform the matrix math described above involve Winograd's algorithm for computing vector inner products. Applying Winograd's algorithm, original polynomial expressions, particularly observed syndromes 204 and current ELP 206, are decomposed into smaller, more manageable sub-polynomials. Expressions for determining discrepancy values for respective iterations of the Berlekamp algorithm are formulated based on the sub-polynomials and stored for use by discrepancy determination control logic 202 to generate computational circuits that implement the same.

Some portions of the expressions for determining discrepancy values based on observed syndromes 204 and coefficients of the current ELP 206 may be precomputed to reduce overall arithmetic operations. Such precomputed values may be stored as intermediate values 214 and used for discrepancy determinations.

Like sub-expressions in respective expressions for determining discrepancy values are identified and those like sub-expressions are stored for use by discrepancy determination control logic 202. The like sub-expressions may be repeated sub-expressions in Berlekamp discrepancy calculations for multiple iterations of the Berlekamp algorithm. During operation, discrepancy determination control logic 202 may generate computational circuits that implement the stored sub-expressions. Values generated by such computational circuits may be stored as intermediate values 214. These sub-expressions may or may not include sub-polynomials, depending on the specific context.

As a non-limiting example involving four (4) erred symbols in a codeword:

For four (4) errors, there are eight (8) discrepancy values, from which the first two, R0 and R1 are expressed as =

$$R o = C [ 00 ] \times S [ 07 ] + C [ 01 ] \times S [ 06 [ + C [ 02 ] \times S [ 05 ] + C [ 03 ] \times S [ 04 ] .$$

$$R 1 = C [ 00 ] \times S [ 08 ] + C [ 01 ] \times S [ 07 ] + C [ 02 ] \times S [ 06 ] + C [ 03 ] \times S [ 05 ] .$$

Where c_x and s_x represent the components of the current ELP and observed syndrome, respectively. Those discrepancy values can be expressed as inner products between vectors, and based on Winograd's inner product algorithm, the expressions may be rewritten as:

$$R 0 = ( C [ 00 ] + S [ 06 ] ) \times ( C [ 01 ] + S [ 07 ] ) + ( C [ 02 ] + S [ 04 ] ) \times ( C [ 03 ] + S [ 05 ] ) - ( C [ 00 ] C [ 01 ] + C [ 02 ] \times C [ 03 ] ) - ( S [ 04 ] \times S [ 05 ] + S [ 06 ] \times S [ 07 ] .$$

$$R 1 = ( C [ 00 ] + S [ 07 ] ) \times ( C [ 01 ] + S [ 08 ] ) + ( C [ 02 ] + S [ 05 ] ) \times ( C [ 03 ] + S [ 06 ] ) - ( C [ 00 ] \times C [ 01 ] + C [ 02 ] \times C [ 03 ] ) - ( S [ 05 ] \times S [ 06 ] + S [ 07 ] \times S [ 08 ] ) .$$

Notably, the sub-expression “(C[00]×C[01]+C[02]×C[03])” is common to R0 and R1 (and R2). So, an intermediate value=(C[00]×C[01]+C[02]×C[03]) may be computed once, stored (as intermediate values 214), and used later. Notably, sub-expressions (S[04]×S[05]+S[06]×S[07]) and (S[05]×S[06]+S[07]×S[08]) depend only on the observed syndromes 204, which are constant, and thus intermediate values based on these sub-expressions may be computed once, stored, and reused.

The number of multipliers utilized by a standard Berlekamp discrepancy calculation engine that corrects up to four error symbols is 4*8=32 multipliers. The number of multipliers utilized by a Berlekamp discrepancy calculation engine in accordance with one or more examples is 2*8+2=18 multipliers. There is a trade-off between multipliers and registers. A typical multiplier, such as a Galois-Field (GF) multiplier, utilizes about 300 gates, while a flip-flop utilizes about 60 gates, so the tradeoff is favorable.

For even iterations of Berlekamp algorithm, the discrepancy determination control logic 202 assigns multipliers 220 and adders 222 via fabric 210 to carry out the determination of discrepancy values for the current even iteration of the Berlekamp algorithm. Discrepancy determination control logic 202 may also assign multipliers 220 and adders 222 via fabric 210 to carry out the determinations of intermediate values that will be used by discrepancy determination control logic 202 during the later iterations (e.g., the next even iteration, without limitation) of the Berlekamp algorithm. Respective ones of multipliers 220 and adders 222 assigned to carry out the determination of intermediate values are different than respective ones of multipliers 220 and adders 222 assigned to carry out the determination of the discrepancy value for the current, even iteration.

For odd iterations of Berlekamp algorithm, since no discrepancy determinations are made during odd iterations of the Berlekamp algorithm, the discrepancy determination control logic 202 can assign any and all multipliers 220 and adders 222 to determine intermediate values needed for future even iterations.

Since the next version of the current ELP 206 could change at the next even iteration of the Berlekamp algorithm, only intermediate values 214 based on one or more of the observed syndromes 204 (or components thereof) or the previous version of the current ELP 206 (or components thereof) are determined during even or odd iterations of the Berlekamp algorithm.

FIG. 3A through FIG. 3G are schematic diagrams depicting instances of computational circuits that may be generated by discrepancy determination circuit 200 to determine discrepancy values and/or intermediate values.

The ‘C’ represents coefficients of the current ELP 206. The ‘S’ represents coefficients of observed syndromes 204. The ‘d’ represents Berlekamp discrepancy values. The ‘m’ represents intermediate values. The ‘n’ represents an iteration of the Berlekamp algorithm.

In the computational circuits depicted in FIG. 3A through FIG. 3G, finite field multipliers are used to implement the inner product operator noted ‘×’ (e.g., ‘C[00]×[C[01]’, without limitation) and finite field adders are used to implement the summation operator denoted by “+” (e.g., ‘S[n+2]+C[00]’, without limitation) are used. Finite field adders are small (an exclusive OR gate may be utilized to implement a finite field adder) and generally may be considered free (i.e., inexpensive). Finite field multipliers are smaller (in terms of hardware space and complexity) than classical multipliers but are still larger than other finite field operators and so reducing the number of finite field multipliers is desirable.

FIG. 3A depicts computational circuits that may be generated by discrepancy determination circuit 200 to determine discrepancy values and intermediate values based on the observed syndromes and coefficients of a current ELP that is a first degree.

Computational circuit 302 determines discrepancy value d[n]. In the case of standard Berlekamp, computational circuit 302 determines a discrepancy value for the current iteration of the Berlekamp algorithm. In examples of an early exit implementation of Berlekamp that evaluates discrepancy values for future iterations, discussed below, computational circuit 302 determines discrepancy values m[n] for iterations n=0:13 in a cycle (i.e., determines fourteen discrepancy values in a cycle of the early exit logic).

The index for ‘C[00]’ is in the format ‘[iteration (or ‘n’), term number]’ so the coefficient for the 0^{th} term in the current ELP is used to determine discrepancy value d[n] for respective iterations n=0:13 of the Berlekamp algorithm. Observed syndromes for n+1 and n+2 iterations are also used to determine discrepancy value d[n] for respective iterations 0:13 of the Berlekamp algorithm.

Computational circuit 304 determines intermediate value m[n] for iterations n=0:6. In one or more examples, discrepancy determination circuit 200 may generate a single instance of computational circuit 304 may be generated and intermediate values m[n] for n=0:6 may be determined sequentially over multiple clock cycles. Alternatively, in one or more examples, discrepancy determination circuit 200 may generate multiple instances of computational circuit 304 and determine multiple intermediate values m[n] on a same clock cycle (in this example, up to seven intermediate values m[n] may be determined on the same clock cycle). In one or more examples, the number of instances of computational circuits generated by discrepancy determination circuit 200 may be at least partially based on, as a non-limiting example, specific operating conditions, such as available hardware (multipliers and adders) in the pool of hardware resources 218 or desired computational speed (e.g., to meet a desired number of clock cycle per task/computation, without limitation), without limitation.

The intermediate values m[n] are determined based on combinations of coefficients of observed syndromes S[n+3]×S[n+2] for respective iterations n=0:6. Intermediate value m[n] for n=0:6 may be stored at memory 212 with intermediate values 214 and utilized later (e.g., by computational circuits generated by discrepancy determination circuit 200, without limitation) whether in a standard implementation of the Berlekamp algorithm or an early exit implementation of the Berlekamp algorithm.

FIG. 3B depicts computational circuits that may be generated by discrepancy determination circuit 200 to determine discrepancy values and intermediate values based on observed syndromes and coefficients of a current ELP that is a second degree.

Computational circuit 306 determines discrepancy values d[n] for iterations n=0:11 of the Berlekamp algorithm. Here, coefficients of two terms of the current ELP are used by computational circuit 306, C[00], and C[001]. Various intermediate values m[n] are used by computational circuit 306 to determine discrepancy values d[n] for iterations n=0:11. Intermediate values m[n] for iterations n=0:6 were determined by computational circuit 304 of FIG. 3 and stored with intermediate values 214.

Computational circuit 308 determines intermediate values m[n] for iterations 7:11 of the Berlekamp algorithm. Intermediate values m[n] for n=7:11 may be stored at memory 212 with intermediate values 214 and utilized later.

In one or more examples, one or more of the intermediate values m[n] for iterations n=7:11 may be determined and stored with intermediate values 214 by computational circuit 308 while computational circuit 306 determines one or more discrepancy values d[n] for the current iteration (in the case of standard implementation of Berlekamp) or iterations n=0:6 (in the case of early exit implementation of Berlekamp). In this manner, the intermediate values m[n] for iterations n=7:11 may be available for determination of discrepancy values d[n] for iterations n=7:11.

FIG. 3C depicts computational circuits that may be generated by discrepancy determination circuit 200 to determine discrepancy values based on observed syndromes, coefficients of a current ELP that is third degree, and various intermediate values that were predetermined as discussed above.

Computational circuit 310 determines discrepancy values d[n] for iterations n=0:11 of the Berlekamp algorithm. Coefficients of three terms of the current ELP are used, C[00], C[001], and C[02]. Intermediate values m[n+2] for iterations n=0:9 are used by computational circuit 310, which were respectively predetermined (e.g., by computational circuits 304 and 308) and stored with intermediate values 214.

FIG. 3D depicts computational circuits that may be generated by discrepancy determination circuit 200 to determine discrepancy values based on observed syndromes, coefficients of a current ELP that is fourth degree, and various intermediate values that were predetermined as discussed above.

Computational circuit 312 determines discrepancy values d[n] for iterations n=0:7 of the Berlekamp algorithm. Coefficients of four terms of the current ELP are used by computational circuit 312, C[00], C[001], C[02], and C[03]. Intermediate values m[n+2] and m[n+4] for iterations n=0:9 are used by computational circuit 312, which were respectively predetermined (e.g., by computational circuits 304 and 308) and stored with intermediate values 214.

FIG. 3E depicts computational circuits that may be generated by discrepancy determination circuit 200 to determine discrepancy values based on observed syndromes, coefficients of a current ELP that is fifth degree, and various intermediate values that were predetermined as discussed above.

Computational circuit 314 determines discrepancy values d[n] for iterations n=0:5 of the Berlekamp algorithm. Coefficients of five terms of the current ELP are used by computational circuit 314, C[00], C[001], C[02], C[03], and C[04]. Intermediate values m[n+2], m[n+4], and m[n+6] for iterations n=0:5 are used by computational circuit 314, which were respectively predetermined (e.g., by computational circuits 304 and 308) and stored with intermediate values 214.

FIG. 3F depicts computational circuits that may be generated by discrepancy determination circuit 200 to determine discrepancy values based on observed syndromes, coefficients of a current ELP that is sixth degree, and various intermediate values that were predetermined as discussed above.

Computational circuit 316 determines discrepancy values d[n] for iterations n=0:3 of the Berlekamp algorithm. Coefficients of six terms of the current ELP are used by computational circuit 316, C[00], C[001], C[02], C[03], C[04], and C[05]. Intermediate values m[n+4], m[n+6], and m[n+8] for iterations n=0:3 are used by computational circuit 316, which were respectively predetermined (e.g., by computational circuits 304 and 308) and stored with intermediate values 214.

FIG. 3G depicts computational circuits that may be generated by discrepancy determination circuit 200 to determine discrepancy values based on observed syndromes, coefficients of a current ELP that is seventh degree, and various intermediate values that were predetermined as discussed above. Here, coefficients of seven terms of the current ELP are used, C[00], C[001], C[02], C[03], C[04], C[05], and C[06].

Computational circuit 318 determines discrepancy values d[n] for iterations n=0:1 of the Berlekamp algorithm. Intermediate values m[n+6], m[n+8], and m[n+10] for iterations n=0:1 are used by computational circuit 318, which were respectively predetermined (e.g., by computational circuits 304 and 308) and stored with intermediate values 214.

Despite the changing state of the ELP over various iterations of the Berlekamp algorithm until convergence, the observed syndrome is constant. Accordingly, intermediate values may be determined, in advance, to be “helper” values for Berlekamp discrepancy determinations. Such helper values may be used during subsequent iterations of the Berlekamp-Massey algorithm, during determinations of discrepancy values for future iterations of the Berlekamp algorithm, or both, to reduce the number of operations, and thus, operators (e.g., multipliers or adders, without limitation), that may otherwise be used to calculate a respective Berlekamp discrepancy value.

Notably, examples discussed herein may be scaled for use in ELP determination for any number of symbol errors. For example, an ELP determination circuit capable of using higher or lower degree ELPs than in the specific examples discussed herein may determine and use intermediate values consistent with the discussion herein.

When examples of discrepancy determination circuit 200 were synthesized, a 43% reduction in overall number of multipliers was realized. When examples of the discrepancy determination circuit 200 were synthesized for 1.2 GHz with a 16 nanometer wafer technology, this incurs a 35% area reduction, a 45% reduction in static power loss (e.g., current leakage), a 20% reduction in dynamic power, and 34% reduction in cell count—as compared to typical implementations. Example reductions are specific, and are not intended to limit the scope of this disclosure in any way.

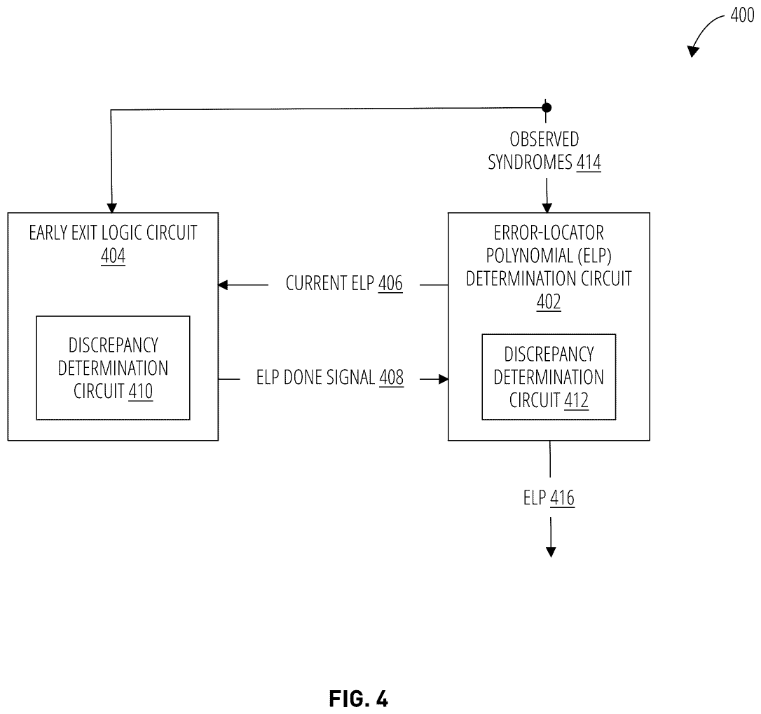

FIG. 4 is a block diagram depicting an apparatus 400 to determine an Error-Locator-Polynomial (ELP) at least partially based on a status signal, where the status signal indicates the status of an ELP determination, in accordance with one or more examples. In one or more examples, a status of the ELP determination (e.g., an ELP determination according to the Berlekamp algorithm, without limitation) may be determined at least partially based on determination of discrepancy values. Efficiency of respective Berlekamp discrepancy determinations in apparatus 400 may be improved (e.g., reduced hardware cost, without limitation) by utilizing a discrepancy determination circuit 200.

Apparatus 400 includes ELP determination circuit 402 and early exit logic circuit 404.

ELP determination circuit 402 generates ELP 416 at least partially based on an observed syndromes 414. ELP determination circuit 402 determines ELP 416 at least partially based on the Berlekamp algorithm that iteratively refines the ELP. During respective iterations, the Berlekamp algorithm determines discrepancy values via discrepancy determination circuit 412, which may be, as a non-limiting example, a discrepancy determination circuit 200 of FIG. 2.

Early exit logic circuit 404 receives observed syndromes 414 and current ELP 406 and sets ELP done signal 408 at least partially based thereon. In one or more examples, early exit logic circuit 404 controls an ELP determination at ELP determination circuit 402 via ELP done signal 408. When asserted, ELP done signal 408 instructs ELP determination circuit 402 to stop the ELP determination (whether or not all 2*t iterations of the Berlekamp algorithm used for the ELP determination are complete), and when de-asserted the ELP done signal 408 instructs ELP determination circuit 402 that an ELP determination may continue. In this manner, early exit logic circuit 404 may use ELP done signal 408 to instruct a conditional exit from an ELP determination utilizing ELP done signal 408. In response to early exit logic circuit 404 asserting ELP done signal 408, ELP determination circuit 102 stops an ELP determination, and provides the current ELP 406 as the ELP 416 for the observed syndromes 414.

Early exit logic circuit 404 sets ELP done signal 408 at least partially based on a determination of the status of the ELP determination being performed by ELP determination circuit 402. Early exit logic circuit 404 may assert ELP done signal 408 at least partially in response to a determination that the ELP determination by ELP determination circuit 402 has reached a stable state, and may de-assert ELP done signal 408 at least partially in response to a determination that the ELP determination by ELP determination circuit 402 has not reached a stable state.

Early exit logic circuit 404 determines the status of the ELP determination based on observed syndromes 414 and early exit logic circuit 404.

Early exit logic circuit 404 determines a status of an ELP determination of the ELP determination circuit 402 and ELP done signal 408 at least partially based on the determined status of the ELP determination, as discussed below. In one or more examples, early exit logic circuit 404 may determine that an ELP determination is in a stable state in response to determining that no changes to the coefficients of the current ELP will occur in further (e.g., future, without limitation) iterations of the ELP determination, as discussed below.

In one or more examples, a discrepancy determination circuit 410 of early exit logic circuit 404 determines discrepancy values for current and subsequent iterations of the ELP determination based on the observed syndromes 414 and current ELP 406, determines whether or not a totality of the determined discrepancy values are zero, and determines the status of the ELP determination based on the determination whether or not a totality of discrepancy values are zero. Discrepancy determination circuit 410 may be, as a non-limiting example, a discrepancy determination circuit 200 of FIG. 2.

In one or more examples, early exit logic circuit 404 determines the status of the ELP determination at even iterations of the ELP determination, but not odd iterations. Thus, the respective current ELP 406 provided to early exit logic circuit 404 are determined during even iterations of the respective ELP determination, and current ELPs determined during odd iterations of the ELP determination are not (e.g., never, without limitation) provided to the early exit logic circuit 404. Thus, in one or more examples, early exit logic circuit 404 only updates the ELP done signal 408 during even iterations of the ELP determination of the ELP determination circuit 402, and does not update the ELP done signal 408 during odd iterations of the ELP determination by the ELP determination circuit 402.

Notably, both ELP determination circuit 402 and early exit logic circuit 404 may enjoy the benefits of reduced hardware resources (e.g., reduced area, reduced power consumption, without limitation) from using discrepancy determination circuits according to discrepancy determination circuit 200.

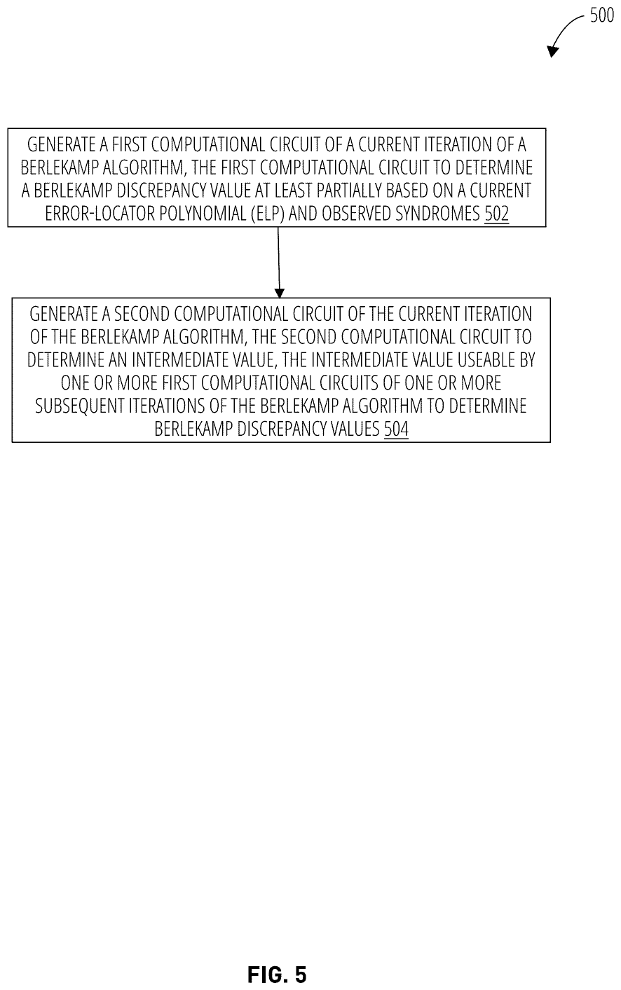

FIG. 5 illustrates an example process 500 for a Berlekamp discrepancy determination, in accordance with one or more example. Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence. Some or a totality of operations of process 500 may be performed, as a non-limiting example, by apparatus 100 of FIG. 1 or discrepancy determination circuit 200 of FIG. 2.

According to one or more examples, process 500 may include generating a first computational circuit of a current iteration of a Berlekamp algorithm, at operation 502. The first computational circuit determines a Berlekamp discrepancy value at least partially based on a current error-locator polynomial (ELP) and observed syndromes.

According to one or more examples, process 500 may include generating a second computational circuit of the current iteration of the Berlekamp algorithm, at operation 504. The second computational circuit determines an intermediate value. The intermediate value is usable by one or more first computational circuits of one or more subsequent iterations of the Berlekamp algorithm to determine Berlekamp discrepancy values.

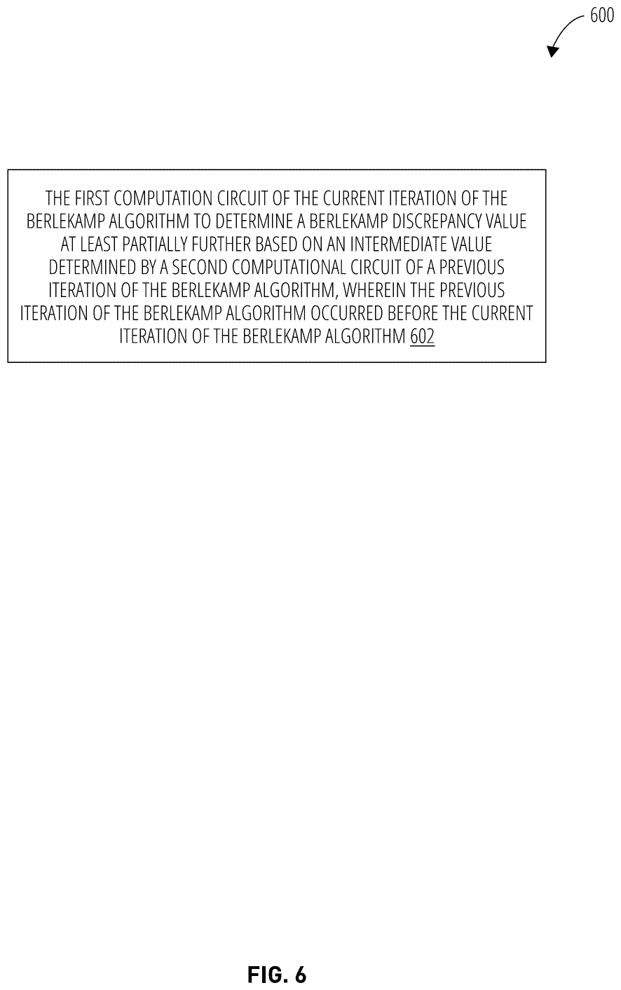

FIG. 6 illustrates an example process 600 for generating the first computational circuit of the current iteration of the Berlekamp algorithm, in accordance with one or more examples. Although the example process 600 depicts a particular sequence of operations, the sequence may be altered without departing from the scope of the present disclosure. For example, some of the operations depicted may be performed in parallel or in a different sequence that does not materially affect the function of the process 600. In other examples, different components of an example device or system that implements the process 600 may perform functions at substantially the same time or in a specific sequence. Some or a totality of operations of process 600 may be performed, as a non-limiting example, by apparatus 100 of FIG. 1 or discrepancy determination circuit 200 of FIG. 2.

According to one or more examples, process 600 may include the first computational circuit of the current iteration of the Berlekamp algorithm to determine a Berlekamp discrepancy value at least partially further based on an intermediate value determined by a second computational circuit of a previous iteration of the Berlekamp algorithm, at operation 602. The previous iteration of the Berlekamp algorithm occurred before the current iteration of the Berlekamp algorithm.

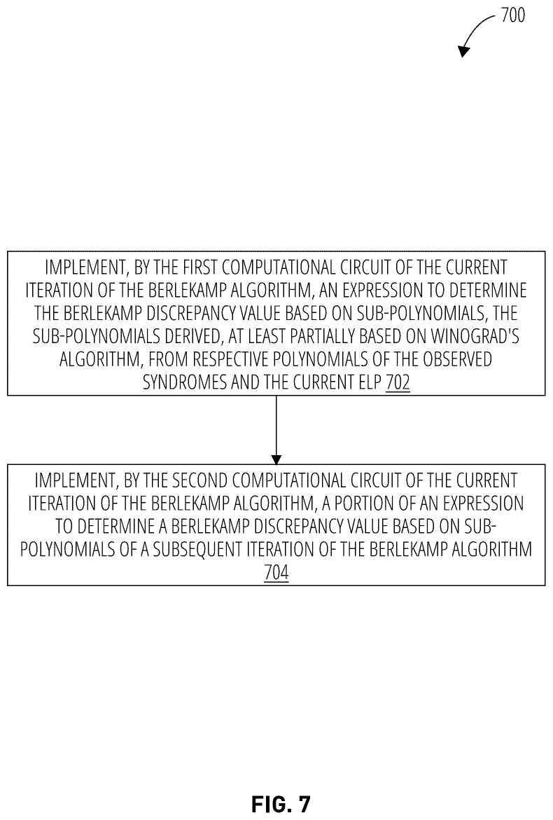

FIG. 7 illustrates an example process 700 for generating the first computational circuit and the second computational circuit of the current iteration of the Berlekamp algorithm, in accordance with one or more examples. Although the example process 700 depicts a particular sequence of operations, the sequence may be altered without departing from the scope of the present disclosure. For example, some of the operations depicted may be performed in parallel or in a different sequence that does not materially affect the function of the process 700. In other examples, different components of an example device or system that implements the process 700 may perform functions at substantially the same time or in a specific sequence. Some or a totality of operations of process 700 may be performed, as a non-limiting example, by apparatus 100 of FIG. 1 or discrepancy determination circuit 200 of FIG. 2.

According to one or more examples, process 700 may include implementing, by the first computational circuit of the current iteration of the Berlekamp algorithm, at operation 702. An expression to determine the Berlekamp discrepancy value based on sub-polynomials. The sub-polynomials derived, at least partially based on Winograd's algorithm, from respective polynomials of the observed syndromes and the current ELP.

According to one or more examples, process 700 may include implementing, by the second computational circuit of the current iteration of the Berlekamp algorithm at operation 704. A portion of an expression to determine a Berlekamp discrepancy value based on sub-polynomials of a subsequent iteration of the Berlekamp algorithm.

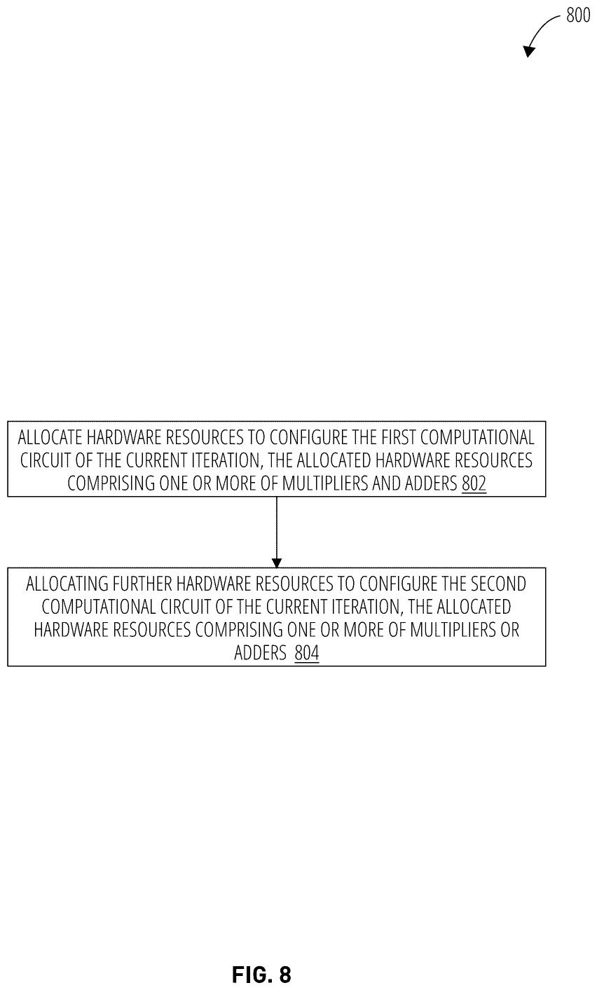

FIG. 8 illustrates an example process 800 for generating the first computational circuit and the second computational circuit of the current iteration of the Berlekamp algorithm, in accordance with one or more examples. Although the example process 800 depicts a particular sequence of operations, the sequence may be altered without departing from the scope of the present disclosure. For example, some of the operations depicted may be performed in parallel or in a different sequence that does not materially affect the function of the process 800. In other examples, different components of an example device or system that implements the process 800 may perform functions at substantially the same time or in a specific sequence. Some or a totality of operations of process 800 may be performed, as a non-limiting example, by apparatus 100 of FIG. 1 or discrepancy determination circuit 200 of FIG. 2.

According to one or more examples, process 800 may include allocating hardware resources to configure the first computational circuit of the current iteration, at operation 802. The assigned hardware resources comprising one or more of multipliers and adders.

According to one or more examples, process 800 may include allocating further hardware resources to configure the second computational circuit of the current iteration, at operation 804. The assigned hardware resources comprising one or more of multipliers or adders.

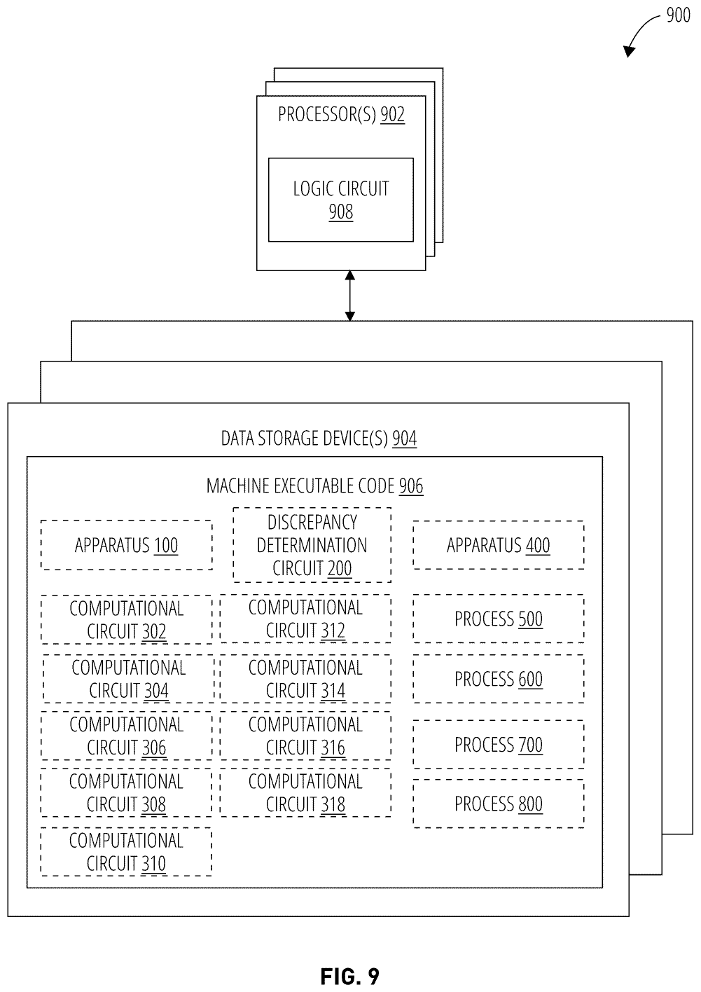

It will be appreciated by those of ordinary skill in the art that functional elements of examples disclosed herein (e.g., functions, operations, acts, processes, or methods) may be implemented in any suitable hardware, software, firmware, or combinations thereof. FIG. 9 illustrates non-limiting examples of implementations of functional elements disclosed herein. In some examples, some or all portions of the functional elements disclosed herein may be performed by hardware specially configured for carrying out the functional elements.

FIG. 9 is a block diagram of a circuitry 900 that, in some examples, may be used to implement various functions, operations, acts, processes, or methods disclosed herein. The circuitry 900 includes one or more processors 902 (sometimes referred to herein as “processors 902”) operably coupled to one or more data storage devices 904 (sometimes referred to herein as “storage 904”). The storage 904 includes machine executable code 906 stored thereon and the processors 902 include logic circuit 908. The machine executable code 906 information describing functional elements that may be implemented by (e.g., performed by) the logic circuit 908. The logic circuit 908 is adapted to implement (e.g., perform) the functional elements described by the machine executable code 906. The circuitry 900, when executing the functional elements described by the machine executable code 906, should be considered as special purpose hardware configured for carrying out functional elements disclosed herein. In some examples, the processors 902 may be configured to perform the functional elements described by the machine executable code 906 sequentially, concurrently (e.g., on one or more different hardware platforms), or in one or more parallel process streams.

When implemented by logic circuit 908 of the processors 902, the machine executable code 906 is configured to adapt the processors 902 to perform operations of examples disclosed herein. By way of non-limiting example, the machine executable code 906 may be configured to adapt the processors 902 to perform some or a totality of operations of Berlekamp discrepancy determinations, and early exit operations discussed above. For example, the machine executable code 906 may be configured to adapt processors 902 to perform some or a totality of operations of process 500, process 600, process 700, or process 800.

Also by way of non-limiting example, the machine executable code 906 may be configured to adapt the processors 902 to perform some or a totality of features, functions, or operations disclosed herein for one or more of apparatus 100 including ELP determination circuit 102; discrepancy determination circuit 200, including discrepancy determination control logic 202, fabric 210, memory 212, pool of hardware resources 218; computational circuit 302, computational circuit 304, computational circuit 306, computational circuit 308, computational circuit 310, computational circuit 312, computational circuit 314, computational circuit 316, or computational circuit 318; or apparatus 400 including ELP determination circuit 402, early exit logic circuit 404, discrepancy determination circuit 410, or discrepancy determination circuit 412.

The processors 902 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer is configured to execute functional elements corresponding to the machine executable code 906 (e.g., software code, firmware code, hardware descriptions) related to examples of the present disclosure. It is noted that a general-purpose processor (may also be referred to herein as a host processor or simply a host) may be a microprocessor, but in the alternative, the processors 902 may include any conventional processor, controller, microcontroller, or state machine. The processors 902 may also be implemented as a combination of computing devices, such as a combination of a DSP and a microprocessor, a plurality of microprocessors, one or more microprocessors in conjunction with a DSP core, or any other such configuration.

In some examples, the storage 904 includes volatile data storage (e.g., random-access memory (RAM)), non-volatile data storage (e.g., Flash memory, a hard disc drive, a solid state drive, erasable programmable read-only memory (EPROM), without limitation). In some examples, the processors 902 and the storage 904 may be implemented into a single device (e.g., a semiconductor device product, a system on chip (SOC), without limitation). In some examples, the processors 902 and the storage 904 may be implemented into separate devices.

In some examples, the machine executable code 906 may include computer-readable instructions (e.g., software code, firmware code). By way of non-limiting example, the computer-readable instructions may be stored by the storage 904, accessed directly by the processors 902, and executed by the processors 902 using at least the logic circuit 908. Also by way of non-limiting example, the computer-readable instructions may be stored on the storage 904, transferred to a memory device (not shown) for execution, and executed by the processors 902 using at least the logic circuit 908. Accordingly, in some examples, the logic circuit 908 includes electrically configurable logic circuit 908.

In some examples, the machine executable code 906 may describe hardware (e.g., circuitry) to be implemented in the logic circuit 908 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, SystemVerilog or very large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 908 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine executable code 906 may include an HDL, an RTL, a GL description, a mask level description, other hardware description, or any combination thereof.

In examples where the machine executable code 906 includes a hardware description (at any level of abstraction), a system (not shown, but including the storage 904) may be configured to implement the hardware description described by the machine executable code 906. By way of non-limiting example, the processors 902 may include a programmable logic device (e.g., an FPGA or a PLC) and the logic circuit 908 may be electrically controlled to implement circuitry corresponding to the hardware description into the logic circuit 908. Also by way of non-limiting example, the logic circuit 908 may include hard-wired logic manufactured by a manufacturing system (not shown, but including the storage 904) according to the hardware description of the machine executable code 906.

Regardless of whether the machine executable code 906 includes computer-readable instructions or a hardware description, the logic circuit 908 is adapted to perform the functional elements described by the machine executable code 906 when implementing the functional elements of the machine executable code 906. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations configured to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: a memory; a pool of hardware resources; a fabric; and a discrepancy determination control logic to generate computational circuits from multipliers and adders of the pool of hardware resources, including: a first computational circuit of a current iteration of a Berlekamp algorithm, the first computational circuit to determine a Berlekamp discrepancy value at least partially based on a current Error-Locator Polynomial (ELP) and observed syndromes respectively stored at the memory; and a second computational circuit of the current iteration of the Berlekamp algorithm, the second computational circuit to determine an intermediate value useable by one or more first computational circuits of one or more subsequent iterations of the Berlekamp algorithm to determine Berlekamp discrepancy values.

Example 2: The apparatus according to Example 1, wherein the discrepancy determination control logic to implement, via the first computational circuit, an expression to determine the Berlekamp discrepancy value based on sub-polynomials, the sub-polynomials derived, at least partially based on Winograd's algorithm, from respective polynomials of the observed syndromes and the current ELP.

Example 3: The apparatus according to Examples 1 and 2, wherein the discrepancy determination control logic to implement, via the second computational circuit, a portion of an expression to determine a Berlekamp discrepancy value based on sub-polynomials of a subsequent iteration of the Berlekamp algorithm.

Example 4: The apparatus according to any of Examples 1 to 3, wherein computational circuits generated by the discrepancy control logic are at least partially based on Winograd's algorithm for vector inner products.

Example 5: The apparatus according to any of Examples 1 to 4, wherein the respective configurations of the computational circuits generated by the discrepancy determination control circuit are iteration-dependent.

Example 6: The apparatus according to any of Examples 1 to 5, wherein the discrepancy determination control logic to assign hardware resources to configure the first computational circuit of the current iteration, the assigned hardware resources comprising one or more of multipliers and adders of the pool of hardware resources.

Example 7: The apparatus according to any of Examples 1 to 6, wherein the discrepancy determination control logic to assign further hardware resources to configure the second computational circuit of the current iteration, the assigned hardware resources comprising one or more of multipliers or adders of the pool of hardware resources.

Example 8: The apparatus according to any of Examples 1 to 7, wherein the second computational circuit implements a repeated sub-expression in Berlekamp discrepancy determinations for multiple iterations of the Berlekamp algorithm.

Example 9: A method comprising: generating a first computational circuit of a current iteration of a Berlekamp algorithm, the first computational circuit to determine a Berlekamp discrepancy value at least partially based on a current Error-Locator Polynomial (ELP) and observed syndromes; and generating a second computational circuit of the current iteration of the Berlekamp algorithm, the second computational circuit to determine an intermediate value, the intermediate value useable by one or more first computational circuits of one or more subsequent iterations of the Berlekamp algorithm to determine Berlekamp discrepancy values.

Example 10: The method according to Example 9, wherein the first computational circuit of the current iteration of the Berlekamp algorithm to determine the Berlekamp discrepancy value at least partially further based on an intermediate value determined by a second computational circuit of a previous iteration of the Berlekamp algorithm, wherein the previous iteration of the Berlekamp algorithm occurred before the current iteration of the Berlekamp algorithm.

Example 11: The method according to Examples 9 and 10, comprising implementing, by the first computational circuit of the current iteration of the Berlekamp algorithm, an expression to determine the Berlekamp discrepancy value based on sub-polynomials, the sub-polynomials derived, at least partially based on Winograd's algorithm, from respective polynomials of the observed syndromes and the current ELP.

Example 12: The method according to any of Examples 9 to 11, comprising implementing, by the second computational circuit of the current iteration of the Berlekamp algorithm, a portion of an expression to determine a Berlekamp discrepancy value based on sub-polynomials of a subsequent iteration of the Berlekamp algorithm.

Example 13: The method according to any of Examples 9 to 12, wherein generating the first computational circuit of the current iteration of the Berlekamp algorithm comprises: allocating hardware resources to configure the first computational circuit of the current iteration, the assigned hardware resources comprising one or more of multipliers and adders.

Example 14: The method according to any of Examples 9 to 13, wherein generating the second computational circuit of the current iteration of the Berlekamp algorithm comprises: allocating further hardware resources to configure the second computational circuit of the current iteration, the assigned hardware resources comprising one or more of multipliers or adders.

Example 15: The method according to any of Examples 9 to 14, comprising: generating the Berlekamp discrepancy value via operation of the generated first computational circuit.

Example 16: A system, comprising: an Error-Locator-Polynomial (ELP) determination circuit; and an early exit logic circuit to set a status signal, the status signal to indicate a status of ELP determination by the ELP determination circuit, wherein the ELP determination circuit to: stop ELP determination at least partially responsive to a first value of the status signal; and continue ELP determination at least partially responsive to a second value of the status signal, wherein the second value different than the first value, wherein the ELP determination circuit and the early exit logic circuit include respective discrepancy determination circuits to determine Berlekamp discrepancy values for a current iteration of a Berlekamp algorithm at least partially based on respective intermediate values determined during a previous iteration of the Berlekamp algorithm.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
a memory;
a pool of hardware resources;
a fabric; and
a discrepancy determination control logic to generate computational circuits from multipliers and adders of the pool of hardware resources, including:
a first computational circuit of a current iteration of a Berlekamp algorithm, the first computational circuit to determine a Berlekamp discrepancy value at least partially based on a current Error-Locator Polynomial (ELP) and observed syndromes respectively stored at the memory; and
a second computational circuit of the current iteration of the Berlekamp algorithm, the second computational circuit to determine an intermediate value useable by one or more first computational circuits of one or more subsequent iterations of the Berlekamp algorithm to determine Berlekamp discrepancy values.

2. The apparatus of claim 1, wherein the discrepancy determination control logic to implement, via the first computational circuit, an expression to determine the Berlekamp discrepancy value based on sub-polynomials, the sub-polynomials derived, at least partially based on Winograd's algorithm, from respective polynomials of the observed syndromes and the current ELP.

3. The apparatus of claim 1, wherein the discrepancy determination control logic to implement, via the second computational circuit, a portion of an expression to determine a Berlekamp discrepancy value based on sub-polynomials of a subsequent iteration of the Berlekamp algorithm.

4. The apparatus of claim 1, wherein the computational circuits generated by the discrepancy determination control logic are at least partially based on Winograd's algorithm for vector inner products.

5. The apparatus of claim 1, wherein the respective configurations of the computational circuits generated by the discrepancy determination control logic are iteration-dependent.

6. The apparatus of claim 1, wherein the discrepancy determination control logic to assign hardware resources to configure the first computational circuit of the current iteration, the assigned hardware resources comprising one or more of multipliers and adders of the pool of hardware resources.

7. The apparatus of claim 6, wherein the discrepancy determination control logic to assign further hardware resources to configure the second computational circuit of the current iteration, the assigned hardware resources comprising one or more of multipliers or adders of the pool of hardware resources.

8. The apparatus of claim 1, wherein the second computational circuit implements a repeated sub-expression in Berlekamp discrepancy determinations for multiple iterations of the Berlekamp algorithm.

9. A method comprising:
generating a first computational circuit of a current iteration of a Berlekamp algorithm, the first computational circuit to determine a Berlekamp discrepancy value at least partially based on a current Error-Locator Polynomial (ELP) and observed syndromes; and
generating a second computational circuit of the current iteration of the Berlekamp algorithm, the second computational circuit to determine an intermediate value, the intermediate value useable by one or more first computational circuits of one or more subsequent iterations of the Berlekamp algorithm to determine Berlekamp discrepancy values.

10. The method of claim 9, wherein the first computational circuit of the current iteration of the Berlekamp algorithm to determine the Berlekamp discrepancy value at least partially further based on an intermediate value determined by a second computational circuit of a previous iteration of the Berlekamp algorithm, wherein the previous iteration of the Berlekamp algorithm occurred before the current iteration of the Berlekamp algorithm.

11. The method of claim 9, comprising implementing, by the first computational circuit of the current iteration of the Berlekamp algorithm, an expression to determine the Berlekamp discrepancy value based on sub-polynomials, the sub-polynomials derived, at least partially based on Winograd's algorithm, from respective polynomials of the observed syndromes and the current ELP.

12. The method of claim 11, comprising implementing, by the second computational circuit of the current iteration of the Berlekamp algorithm, a portion of an expression to determine a Berlekamp discrepancy value based on sub-polynomials of a subsequent iteration of the Berlekamp algorithm.

13. The method of claim 9, wherein generating the first computational circuit of the current iteration of the Berlekamp algorithm comprises:
allocating hardware resources to configure the first computational circuit of the current iteration, the assigned hardware resources comprising one or more of multipliers and adders.

14. The method of claim 9, wherein generating the second computational circuit of the current iteration of the Berlekamp algorithm comprises:
allocating further hardware resources to configure the second computational circuit of the current iteration, the assigned hardware resources comprising one or more of multipliers or adders.

15. The method of claim 9, comprising:
generating the Berlekamp discrepancy value via operation of the generated first computational circuit.

16. A system, comprising:
an Error-Locator-Polynomial (ELP) determination circuit; and
an early exit logic circuit to set a status signal, the status signal to indicate a status of ELP determination by the ELP determination circuit,
wherein the ELP determination circuit to:
stop ELP determination at least partially responsive to a first value of the status signal; and
continue ELP determination at least partially responsive to a second value of the status signal, wherein the second value different than the first value,
wherein the ELP determination circuit and the early exit logic circuit include respective discrepancy determination circuits to determine Berlekamp discrepancy values for a current iteration of a Berlekamp algorithm at least partially based on respective intermediate values determined during a previous iteration of the Berlekamp algorithm.
